(19) United States
(12) Patent Application Publication
(10) Pub. No.: US 2018/0164171 A1
(43) Pub. Date: Jun. 14, 2018

(54) METHOD OF CORRECTING ESTIMATED FORCE OF BONDING APPARATUS

(71) Applicant: SAMSUNG ELECTRONICS CO., LTD., Suwon-si (KR)

(72) Inventors: YOUNGHO HWANG, Hwaseong-si (KR); JANGHWAN KIM, Suwon-si (KR)

(21) Appl. No.: 15/838,583

(22) Filed: Dec. 12, 2017

(30) Foreign Application Priority Data
Dec. 14, 2016 (KR) 10-2016-0170572

(51) Int. Cl. G01L 5/00; H01L 23/00

(52) U.S. Cl. CPC G01L 5/0076; H01L 2021/603; H01L 24/741; H01L 24/64

(57) ABSTRACT

Provided is a method of correcting an estimated force of a bonding apparatus including measuring a first pressure of a first space in a chamber of a bonding apparatus and a second pressure of a second space in the chamber in a first state. In the first state a pressuring member is at rest within the chamber. The pressuring member is moveable within the chamber. The method includes obtaining a first estimated force. The first estimated force is an estimated force of the pressuring member in the first state, using the measured first and second pressures. The method includes obtaining a first error. The first error is a difference between a first real force and the first estimated force. The first real force is a real force of the pressuring member in the first state. The method includes correcting the first estimated force using the first error.

### CROSS-REFERENCE TO RELATED APPLICATION

This U.S. non-provisional patent application claims priority under 35 U.S.C. § 119 to Korean Patent Application No. 10-2016-0170572, filed on Dec. 14, 2016, in the Korean Intellectual Property Office, the disclosure of which is incorporated by reference herein in its entirety.

### TECHNICAL FIELD

Exemplary embodiments of the present inventive concept relate to a bonding apparatus, and more particularly to a method of correcting an estimated force of a bonding apparatus.

### DISCUSSION OF RELATED ART

Relatively high-performance, high-speed and compact electronic systems are seeing increasing demand. Methods for manufacturing compact electronic systems may include stacking a plurality of semiconductor chips on a substrate within a single package. A plurality of such packages may be stacked to produce a “package-on-package (PoP)” device. In such methods, a bonding process may be used to connect the substrate to the semiconductor chip or the stacked semiconductor chips to each other via connection terminals (e.g., solders and pads).

### SUMMARY

An exemplary embodiment of the present inventive concept provides a method of correcting an estimated force of a bonding apparatus and increasing process efficiency in a bonding process.

According to an exemplary embodiment of the present inventive concept, a method of correcting an estimated application of a force includes measuring a first pressure of a first space in a chamber of a bonding apparatus and a second pressure of a second space in the chamber in a first state. In the first state a pressuring member is at rest within the chamber. The pressuring member is moveable within the chamber. The method includes obtaining a first estimated force. The first estimated force is an estimated force of the pressuring member in the first state, using the measured first and second pressures. The method includes obtaining a first error. The first error is a difference between a first real force and the first estimated force. The first real force is a real force of the pressuring member in the first state. The method includes correcting the first estimated force using the first error.

According to an exemplary embodiment of the present inventive concept, a method of correcting an estimated application of a force includes measuring a first pressure of a first space in a chamber and a second pressure of a second space in the chamber. A pressuring member positioned in the chamber is moveable. A first real force exerted on the pressuring member is zero. The method includes obtaining a first estimated force. The first estimated force is a force expected to be exerted on the pressuring member in a first state. The first estimated force is obtained using the measured first and second pressures. The method includes obtaining a first error. The first error is a difference between the first real force and the first estimated force.

The method includes correcting the first estimated force using the first error.

### BRIEF DESCRIPTION OF THE DRAWINGS

The above and other features of the inventive concept will become more apparent by describing in detail exemplary embodiments thereof, with reference to the accompanying drawings, in which:

FIG. 1 is a plan view illustrating a substrate processing system according to an exemplary embodiment of the present inventive concept.

FIG. 2 is a perspective view illustrating the bonding apparatus of FIG. 1.

FIG. 3 is a side view illustrating the bonding apparatus of FIG. 1.

FIG. 4 is a schematic diagram illustrating a portion of the bonding apparatus of FIG. 1.

FIG. 5 is an enlarged view of a portion ‘A’ of FIG. 4.

FIG. 6 is a block diagram illustrating a portion of the bonding apparatus of FIG. 1.

FIG. 7 is a schematic diagram illustrating a modified example of the bonding apparatus of FIG. 4.

FIG. 8 is a flow chart illustrating an example of a method of correcting an estimated force of the bonding apparatus of FIG. 1.

FIG. 9 is a flow chart illustrating a step of correcting a second real force, shown in FIG. 8.

FIG. 10 is a flow chart illustrating a step of correcting a third estimated force using first and second errors, shown in FIG. 8.

FIG. 11 is a diagram showing an estimated force and a real force, when first and second errors of FIG. 8 correspond to each other.

FIG. 12 is a diagram showing an estimated force and a real force, when first and second errors of FIG. 8 do not correspond to each other.

FIG. 13 is a flow chart illustrating another example of a method of correcting an estimated force of the bonding apparatus of FIG. 1.

FIG. 14 is a flow chart illustrating a step of obtaining a first estimated force, shown in FIG. 13.

FIG. 15 is a flow chart illustrating a step of obtaining a first real force, shown in FIG. 13.

### DETAILED DESCRIPTION

Exemplary embodiments of the present inventive concept will be described below in more detail with reference to the accompanying drawings. In this regard, the present inventive concept may have different forms and should not be construed as being limited to the exemplary embodiments of the present inventive concept described herein. Like reference numerals may refer to like elements throughout the specification and drawings.

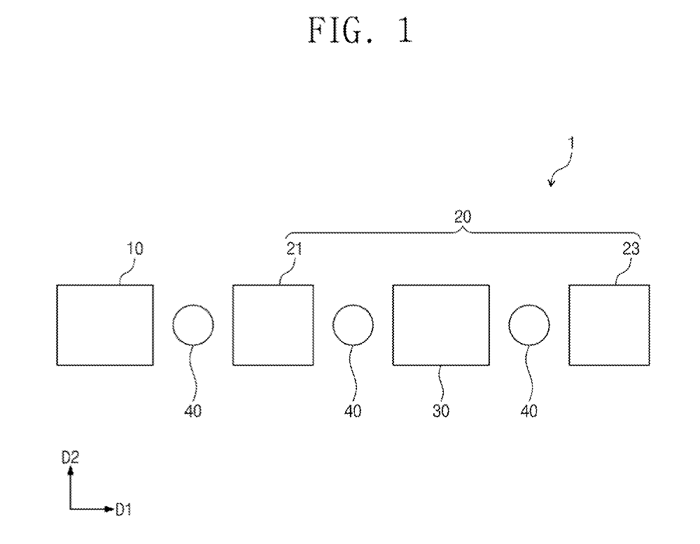

FIG. 1 is a plan view illustrating a substrate processing system according to an exemplary embodiment of the present inventive concept.

Referring to FIG. 1, a substrate processing system 1 according an exemplary embodiment of the present inventive concept may be configured to perform a process of bonding electric connection terminals (e.g., solders and pads) between a substrate and a semiconductor chip. As an example, the electric connection terminals may be bonded between stacked semiconductor chips. The substrate processing system 1 may include a mounting apparatus 10, an inspection apparatus 20, and a bonding apparatus 30.

The mounting apparatus 10 may be configured to perform a process of mounting a semiconductor chip on a substrate. The bonding apparatus 30 may be configured to perform the process of bonding electric connection terminals between a semiconductor chip and a substrate and between stacked semiconductor chips. For example, the bonding apparatus 30 may be configured to exert pressure on the stacked semiconductor chips during the bonding process.

The inspection apparatus 20 may include a mounting inspection unit 21 and a bonding inspection unit 23. The mounting inspection unit 21 may be positioned between the mounting apparatus 10 and the bonding apparatus 30. The mounting inspection unit 21 may be used to examine whether a semiconductor chip is in a predetermined position aligned with a substrate or other semiconductor chips. For example, the mounting inspection unit 21 may be used to examine whether a semiconductor chip is in a predetermined position aligned with a substrate or other semiconductor chips when the mounting process is finished.

The bonding inspection unit 23 may be used to examine whether a semiconductor chip is in the predetermined position aligned with a substrate or other semiconductor chips (e.g., when the bonding process is finished). In an exemplary embodiment of the present inventive concept, the mounting inspection unit 21 and/or the bonding inspection unit 23 may be omitted in the substrate processing system 1.

In an exemplary embodiment of the present inventive concept, the mounting apparatus 10, the mounting inspection unit 21, the bonding apparatus 30, and the bonding inspection unit 23 may be respectively adjacent to each other. Transfer units 40, which may be used to transfer a substrate, may be respectively provided between the mounting apparatus 10 and the mounting inspection unit 21, between the mounting inspection unit 21 and the bonding apparatus 30, and between the bonding apparatus 30 and the bonding inspection unit 23. In an exemplary embodiment of the present inventive concept, the mounting apparatus 10, the inspection apparatus 20, and the bonding apparatus 30 may be sequentially arranged along a line (e.g., a line extending substantially along a first direction D1). In an exemplary embodiment of the present inventive concept, the mounting apparatus 10 and the inspection apparatus 20 may be arranged substantially along the first direction D1, and the inspection apparatus 20 and the bonding apparatus 30 may be arranged substantially along a second direction D2 crossing the first direction. As an example, the first and second directions D1 and D2 may be perpendicular to each other, when viewed in a plan view. The mounting apparatus 10, the inspection apparatus 20, and the bonding apparatus 30 may be spaced apart from each other, and thus, a container, which can contain a plurality of substrates, may be used to transfer at least one substrate from one of the apparatuses to another. The container may be a magazine holding printed circuit boards or a front opening unified pod (FOUP) holding wafers.

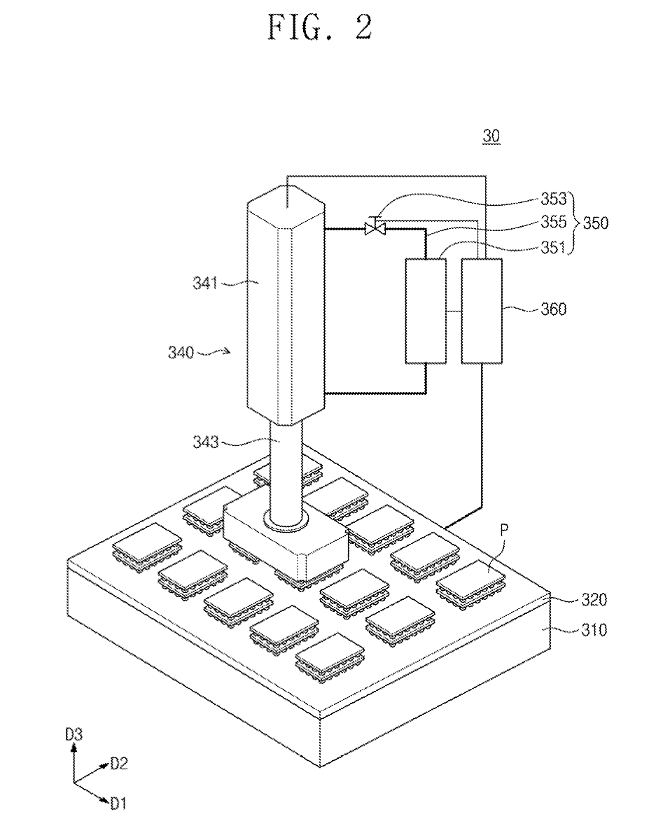

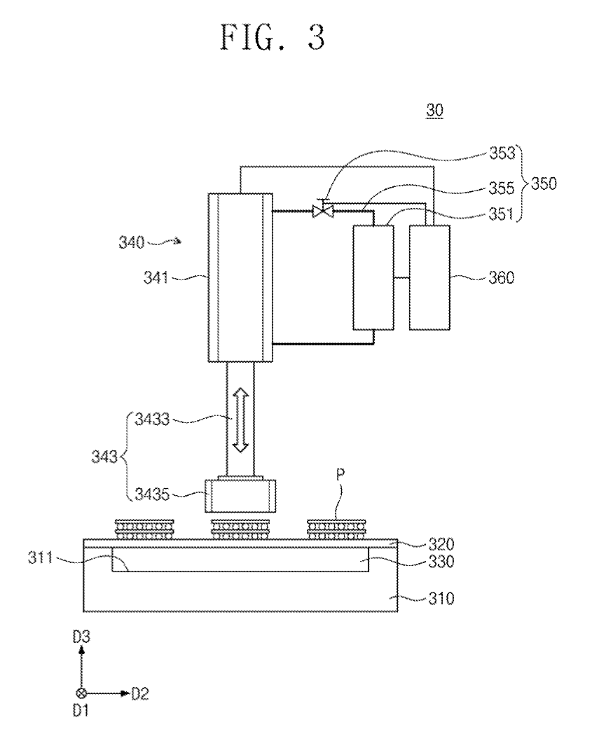

FIG. 2 is a perspective view illustrating the bonding apparatus of FIG. 1. FIG. 3 is a side view illustrating the bonding apparatus of FIG. 1.

Referring to FIGS. 2 and 3, the bonding apparatus 30 may include a base 310, a supporting member 320, a heating member 330, a pressuring unit 340, a pressure supply unit 350, and a controller 360. The base 310 may be configured to support the supporting member 320 and the heating member 330. The base 310 may include an insertion opening 311. The heating member 330 may be positioned in the insertion opening 311.

The heating member 330 may be configured to heat a substrate and/or a plurality of stacked semiconductor chips P. The stacked semiconductor chips P may be interchangeably referred to as a target object P. As an example, the heating member 330 may be configured to provide heat energy to a bottom surface of the target object P.

The supporting member 320 may be positioned on the base 310. The target object P may be positioned on the supporting member 320. The supporting member 320 may substantially cover the insertion opening 311. The supporting member 320 may be positioned between the heating member 330 and the target object P. Thus, the supporting member 320 may prevent the heating member 330 and the target object P from being in direct contact with each other.

The pressuring unit 340 may be spaced apart from the supporting member 320 along a direction orthogonal to the first and second directions D1 and D1 (e.g., a third direction D3), such as when pressure is not being applied to the target object P on the supporting member 320. For example, the pressuring unit 340 may be spaced apart from the supporting member 320 in a third direction D3 that is perpendicular to the first and second directions D1 and D2. The pressuring unit 340 may press the target object P against the supporting member 320. As an example, the pressuring unit 340 may be configured to exert a force on the target object P. In an exemplary embodiment of the present inventive concept, the bonding apparatus 30 may include a plurality of pressuring units 340. A transfer unit may move the pressuring unit 340 over the supporting member 320 in the first and second directions D1 and D2.

The pressuring unit 340 may include a chamber 341 and a pressuring member 343. A portion of the pressuring member 343 may be positioned in the chamber 341. The pressuring member 343 may be configured to move in the third direction D3. For example, the pressuring member 343 may be moved in a vertical direction. The pressuring unit 340 will be described in more detail below.

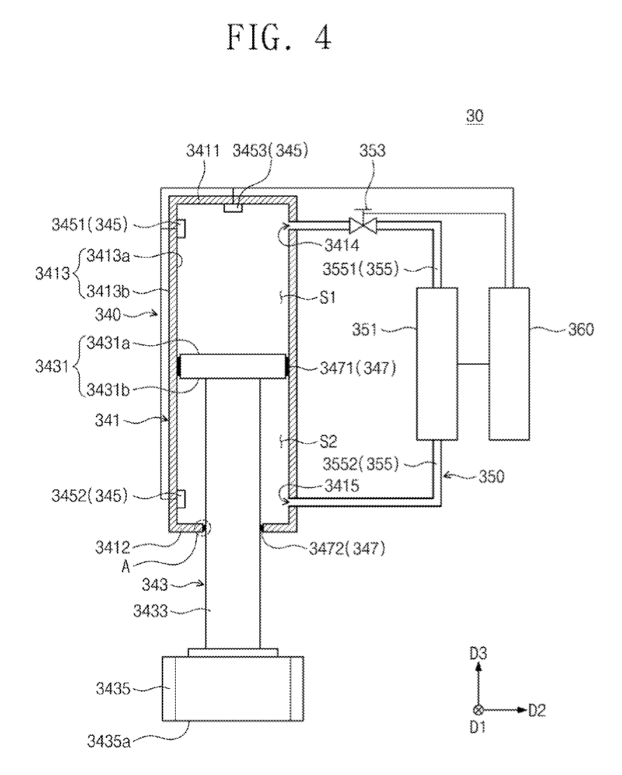

The pressure supply unit 350 may be configured to apply a pressure to the pressuring unit 340. The pressure supply unit 350 may include a pressure generating part 351, which is configured to generate the pressure, a connection line structure 355, which connects the pressure generating part 351 to the pressuring unit 340, and a pressure control part 353, which is configured to control a force of pressure applied to the pressuring unit 340. The application of pressure to the pressuring unit 340 will be described in more detail below with reference to FIG. 4.

The controller 360 may control the pressure generating part 351, the pressure control part 353, and the heating member 330. For example, under the control of the controller 360 and depending on a process step, the pressure generating part 351, the pressure control part 353, and the heating member 330 may be controlled to adjust heating time and heating temperature of the target object P and a magnitude of force to be applied on the target object P. This will be described in more detail below.

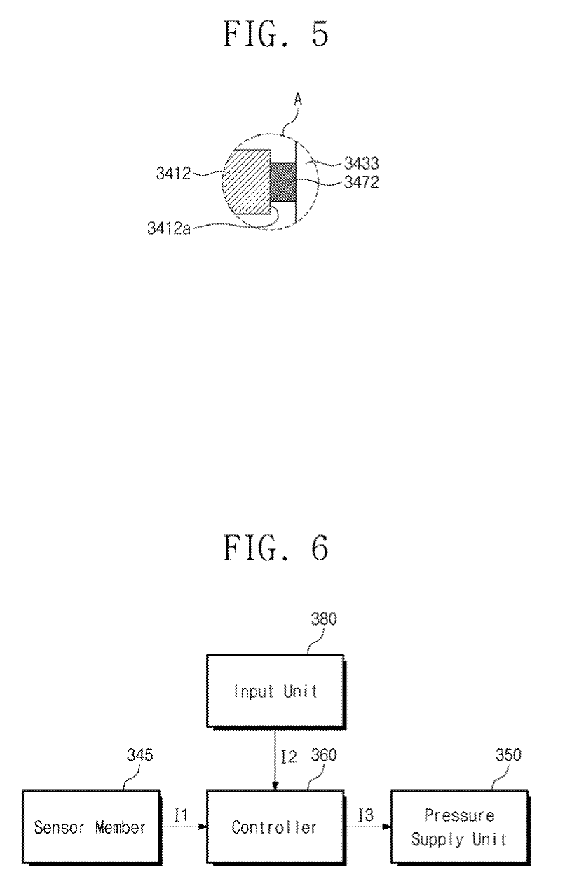

FIG. 4 is a schematic diagram illustrating a portion of the bonding apparatus of FIG. 1. FIG. 5 is an enlarged view of a portion ‘A’ of FIG. 4. FIG. 6 is a block diagram illustrating a portion of the bonding apparatus of FIG. 1.

Referring to FIGS. 3 to 6, the bonding apparatus 30 may include the pressuring unit 340, the pressure supply unit 350, and the controller 360. The bonding apparatus 30 may further include an input unit 380.

The pressuring unit 340 may include the chamber 341, the pressuring member 343, a sensor member 345, and a bearing member 347. The chamber 341 may be a substantially cylindrical structure with an internal space. The chamber 341 may include an upper wall 3411, a lower wall 3412, and a side wall 3413. The side wall 3413 may connect the upper wall 3411 to the lower wall 3412. The side wall 3413 may include an inner side surface 3413a adjacent to the pressuring member 343 and an outer side surface 3413b facing the inner side surface 3413a. A through hole 3412a may be formed through a surface of the chamber 341 facing the target object P. For example, the through hole 3412a may be formed through the lower wall 3412 of the chamber 341.

A portion of the pressuring member 343 may be positioned in the chamber 341. The pressuring member 343 may be movable in the chamber 341. For example, the pressuring member 343 may be configured to perform a reciprocating motion substantially parallel to the third direction D3 within the chamber 341. The pressuring member 343 may divide the internal space of the chamber 341 into a first space S1 and a second space S2. For example, the chamber 341 may be a cylinder, and the pressuring member 343 may be a piston.

The second space S2 may be closer to the target object P than the first space S1 along the third direction D3. For example, the second space S2 may be positioned below the first space S1 and may be closer to the supporting member 320 (see, e.g., FIG. 3) than the first space S1. The second space S2 may be connected to the through hole 3412a. The first space S1 may be connected to a first inlet hole 3414 of the side wall 3413, and the second space S2 may be connected to a second inlet hole 3415 of the side wall 3413. A volume of each of the first and second spaces S1 and S2 may be changed depending on the motion of the pressuring member 343. The sum of the volumes of the first and second spaces S1 and S2 may remain substantially constant.

The pressuring member 343 may include a head part 3431, a rod part 3433, and a contact part 3435. The head part 3431 may have a width that is smaller than an inner diameter of the chamber 341. The inner diameter of the chamber 341 may be a distance between opposite portions of the inner side surface 3413a. The head part 3431 may include a first surface 3431a and a second surface 3431b facing away from each other. The first surface 3431a may be positioned in the first space S1. The second surface 3431b may be positioned in the second space S2. For example, the first surface 3431a may be a top surface of the head part 3431 facing away from the supporting member 320 (see, e.g., FIG. 3), and the second surface 3431b may be a bottom surface of the head part 3431 facing toward the supporting member 320 (see, e.g., FIG. 3).

The rod part 3433 may be a pillar-shaped structure extending from the head part 3431 toward the target object P. For example, the rod part 3433 may extend along the vertical direction (e.g., the third direction D3) and may have a substantially circular pillar shape. The rod part 3433 may connect the head part 3431 to the contact part 3435. The head part 3431 may be connected to an end of the rod part 3433, and the contact part 3435 may be connected to an opposite end of the rod part 3433. The rod part 3433 may be positioned on the second surface 3431b. The rod part 3433 may overlap the second surface 3431b along the third direction D3, when viewed in a plan view. The second surface 3431b may have an area that is less than that of the first surface 3431a. A width of the rod part 3433 may be less than that of the head part 3431. The width of the rod part 3433 may be less than that of the through hole 3412a. The rod part 3433 may pass through the through hole 3412a.

The contact part 3435 may come into direct contact with the target object P (e.g., with an upper surface of the target object P facing away from the supporting member 320). The contact part 3435 may have a contact surface 3435a facing the target object P. The contact surface 3435a may include an elastic material. Thus, a magnitude of impact exerted on the target object P from the contact surface 3435a may be reduced, and thus damaged to the target object may be reduced or eliminated. The contact part 3435 may include a sub-heating member. The sub-heating member may be used to heat an upper portion of the target object P.

The sensor member 345 may be used to measure a pressure of each of the first and second spaces S1 and S2 and a position of the pressuring member 343. The sensor member 345 may include a first pressure sensor 3451, a second pressure sensor 3452, and a position sensor 3453.

The first and second pressure sensors 3451 and 3452 may be positioned on the inner side surface 3413a of the chamber 341. The first pressure sensor 3451 may be positioned within the first space S1. Thus, the first pressure sensor 3451 may be used to measure the pressure of the first space S1. The second pressure sensor 3452 may be positioned within the second space S2. Thus, the second pressure sensor 3452 may be used to measure the pressure of the second space S2. Pressure data obtained using the first and second pressure sensors 3451 and 3452 may be transmitted to the controller 360.

In an exemplary embodiment of the present inventive concept, the position sensor 3453 may be positioned within the chamber 341. For example, the position sensor 3453 may be positioned within the first space S1 and on an inner surface of the upper wall 3411; however, a position of the position sensor 3453 is not limited thereto. The position sensor 3453 may be used to measure a distance to the first surface 3431a of the head part 3431 from the position sensor 3453. As an example, the position sensor 3453 may be a laser sensor or an ultrasonic wave sensor. Distance data measured by the position sensor 3453 may be transmitted to the controller 360. In the controller 360, the distance data may be used to obtain position data on the pressuring member 343.

The bearing member 347 may be positioned between the pressuring member 343 and the chamber 341. The bearing member 347 may include a first bearing 3471, which is positioned between the head part 3431 and the inner side surface 3413a of the chamber 341, and a second bearing 3472, which is positioned between an inner side surface of the through hole 3412a and the rod part 3433. The first and second bearings 3471 and 3472 may be air bearings. The first bearing 3471 may be positioned between the first and second spaces S1 and S2 and may separate the first and second spaces S1 and S2 from each other.

The pressure supply unit 350 may be configured to provide pressure to the pressuring unit 340. For example, the pressure supply unit 350 may provide pressure to the first and second spaces S1 and S2 of the chamber 341. The pressure may be used to exert a force on the pressuring member 343. Since the force is exerted on the pressuring member 343, the pressuring unit 340 may be used to exert force on the target object P. The pressure supply unit 350 may include the pressure generating part 351, the pressure control part 353, and the connection line structure 355.

The pressure generating part 351 may be configured to generate a predetermined pressure. The pressure generating part 351 may be connected to the internal space of the chamber 341 through the connection line structure 355. For example, the pressure generating part 351 may be connected to the first and second spaces S1 and S2. Thus, the pressure generating part 351 may provide a predetermined pressure to the first and second spaces S1 and S2. The pressure generating part 351 may be configured to generate fluid pressure (e.g., air pressure); however, exemplary embodiments of the present inventive concept are not limited thereto. For example, the pressure generating part 351 may be an air compressor.

The connection line structure 355 may connect the pressure generating part 351 to the inner space of the chamber 341. The connection line structure 355 may include a first connection line 3551, which connects the pressure generating part 351 to the first inlet hole 3414, and a second connection line 3552, which connects the pressure generating part 351 to the second inlet hole 3415.

The pressure control part 353 may be positioned on the first connection line 3551. The pressure control part 353 may be configured to control pressure of the first space S1. The pressure control part 353 may be a servo valve. A switching operation of the pressure control part 353 can be controlled by an electric input signal; however, exemplary embodiments of the present inventive concept are not limited thereto.

The controller 360 may be configured to control the pressure control part 353 and the pressure generating part 351. For example, the controller 360 may receive a sensor signal I1 from the sensor member 345 and an input signal I2 from the input unit 380. The input signal I2 may include data on a force that should be exerted on the target object P by the bonding apparatus 30. The controller 360 may transmit a control signal 13, in which pressure data corresponding to the force data is contained, to the pressure supply unit 350. The pressure data may include data on a value of pressure to be generated in the pressure generating part 351 and on a value of the pressure controlled by the pressure control part 353. Thus, the controller 360 may control pressure to be provided to the second space S2, through the pressure generating part 351. The controller 360 may control pressure to be provided to the first space S1, through the pressure control part 353. A value of pressure to be controlled by the pressure control part 353 may correspond to a value of pressure to be provided to the first space S1. A value of pressure to be generated by the pressure generating part 351 may correspond to a value of pressure to be provided to the second space S2. The controller 360 will be described in more detail below.

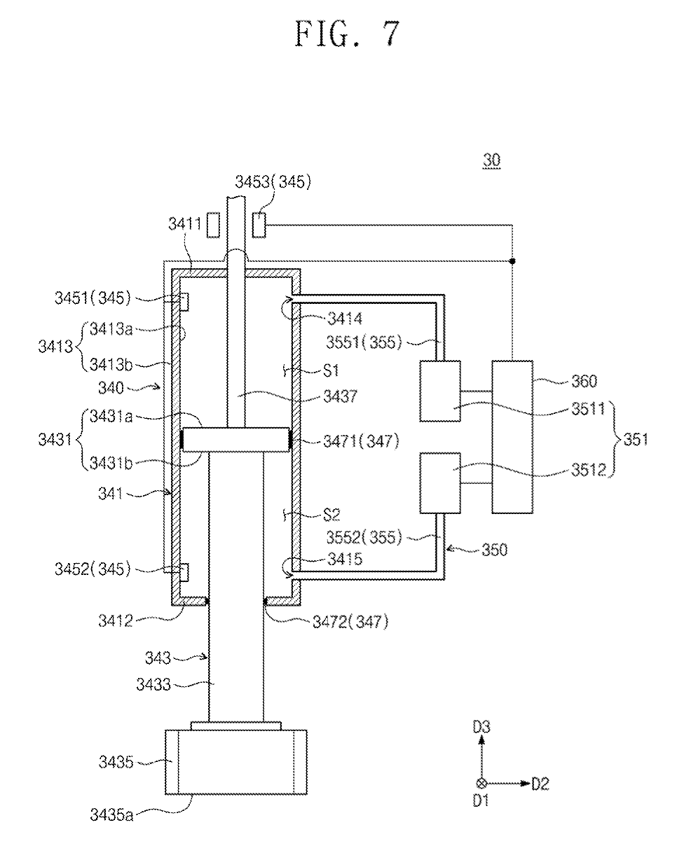

FIG. 7 is a schematic diagram illustrating a modified example of the bonding apparatus of FIG. 4. Element previously described above (e.g., with reference to FIG. 4) may be the same as those described below with reference to FIG. 7, and thus duplicative descriptions may be omitted.

Referring to FIGS. 4 and 7, the bonding apparatus 30 may include the pressuring unit 340, the pressure generating part 351, and the connection line structure 355, the controller 360. Unlike the bonding apparatus 30 described above with reference to FIG. 4, the pressure control part 353 may be omitted from the bonding apparatus 30 described with reference to FIG. 7.

The pressuring unit 340 may include the chamber 341, the pressuring member 343, the sensor member 345, and the bearing member 347. Unlike the chamber 341 described above with reference to FIG. 4, the chamber 341 may have an upper hole, which is formed to penetrate the upper wall 3411.

The pressuring member 343 may include the head part 3431, the rod part 3433, and the contact part 3435. Unlike the pressuring member 343 described above with reference to FIG. 4, the pressuring member 343 may include a sub-rod part 3437 positioned on the first surface 3431a of the head part 3431. The sub-rod part 3437 may be connected to the head part 3431. The sub-rod part 3437 may pass through an upper hole 3411a. The sub-rod part 3437 may extend substantially along the third direction D3. The sub-rod part 3437 may include a scale indicating a length on the outer side surface 3413b. The scale may be configured to express a position of the sub-rod part 3437. The scale may extend along a length direction (e.g., along the third direction D3) of the sub-rod part 3437. The sub-rod part 3437 may be movable in the length direction thereof (e.g., along the third direction D3). As an example, the sub-rod part 3437 may be movable in a vertical direction.

Unlike the position sensor 3453 described above with reference to FIG. 4, the position sensor 3453 may be positioned outside the chamber 341. The position sensor 3453 may be positioned adjacent to a moving path of the sub-rod part 3437. The position sensor 3453 may be configured to obtain data on the linear scale of the sub-rod part 3437. For example, the position sensor 3453 may be a scanner for measuring the data on the linear scale of the sub-rod part 3437; however, exemplary embodiments of the present inventive concept are not limited thereto.

The pressure generating part 351 may include a first pressure generating part 3511, which is configured to provide pressure to the first space S1, and a second pressure generating part 3512, which is configured to provide pressure to the second space S2. At least one of the first and second pressure generating parts 3511 and 3512 may be configured to change the pressure generated thereby. The first and second pressure generating parts 3511 and 3512 may be used to change the pressure of at least one of the first and second spaces S1 and S2, respectively.

The controller 360 may receive an input signal through an input unit. Pressure data corresponding to the input signal may include values of pressures, which will be respectively generated by the first and second pressure generating parts 3511 and 3512. As an example, the first and second pressure generating parts 3511 and 3512 may be respectively controlled by the controller 360, and this may make it possible to independently control pressures to be provided to the first and second spaces S1 and S2.

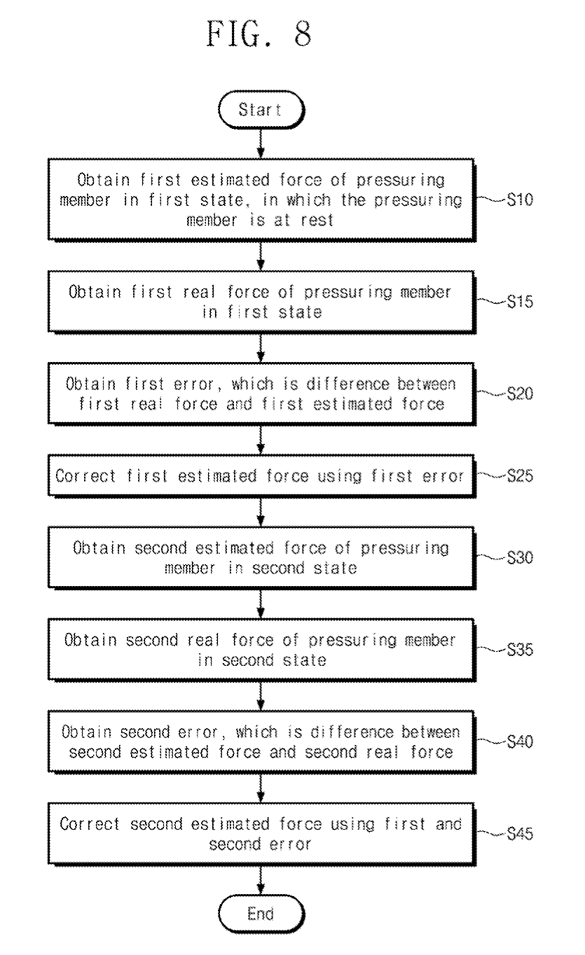

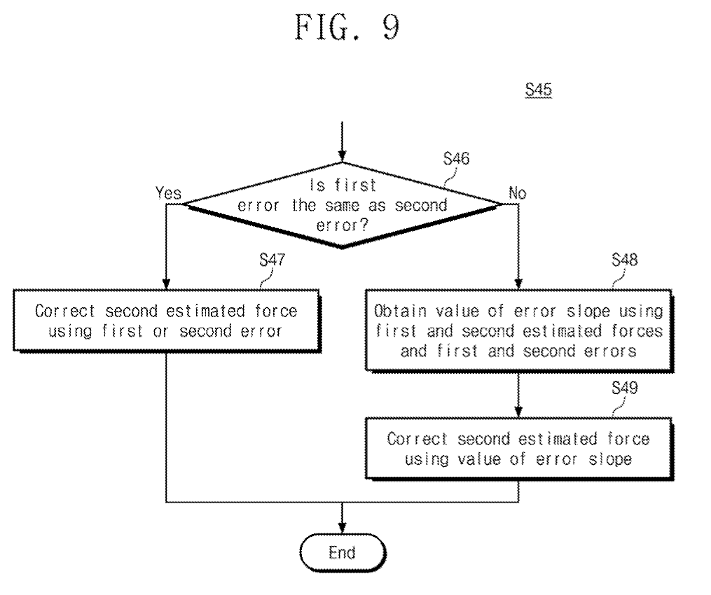

FIG. 8 is a flow chart illustrating an example of a method of correcting an estimated force of the bonding apparatus of FIG. 1. FIG. 9 is a flow chart illustrating a step of correcting a second real force, shown in FIG. 8.

Referring to FIGS. 2 and 8, the bonding apparatus 30 may be generally configured in such a way that an estimated force corresponds to a real force. However, there may be a variation in pressure provided from the pressure supply unit 351 and/or in tension of a cable connected to the pressuring member 343, and this may lead to a difference between the estimated force and the real force or an error in measurement of the force. The difference between the estimated force and the real force may cause deterioration in bonding efficiency of the target object P or breakage of the target object P during a bonding process. Thus, the estimated force of the bonding apparatus 30 may be corrected.

A method of correcting an estimated force of a bonding apparatus, an exemplary embodiment of the present inventive concept, will be described in more detail below with reference to FIGS. 2 to 6, 8, and 9.

The method of correcting an estimated force of a bonding apparatus may include obtaining a first estimated force, which is an estimated force of a pressuring member in a first state (in S10). The obtaining of the first estimated force may include determining whether the pressuring member 343 is in a stationary state, and then, measuring pressures of the first and second spaces S1 and S2 when the pressuring member 343 is in the stationary state.

To determine whether the pressuring member 343 is in the stationary state, the position sensor 3453 may measure a position of the pressuring member 343. As an example, the position sensor 3453 may obtain position data of the pressuring member 343. The controller 360 may receive the position data, which is obtained by the position sensor 3453. In the controller 360, the position data and a predetermined time data may be used to determine whether the pressuring member 343 is in the stationary state. For example, based on the position data and the time data, the controller 360 may determine whether the pressuring member 343 is positioned at the same position during a predetermined time interval. If the pressuring member 343 is positioned at the same position during a predetermined time interval (e.g., without moving during the predetermined time period), the controller 360 may determine that the pressuring member 343 is stationary within a chamber 361. When the pressuring member 343 is in the stationary state within the chamber 361, it may be positioned at a predetermined position. In an exemplary embodiment of the present inventive concept, when the pressuring member 343 is in the stationary state within the chamber 361, it may be positioned at an arbitrary position.

The measuring of the pressures of the first and second spaces S and S2 may be performed. As an example, when the pressuring member 343 is in the first state (e.g., stationary state) within the chamber 341, the first pressure sensor 3451 may measure a first pressure of the first space S1 and the second pressure sensor 3452 may measure a second pressure of the second space S2. The measured first pressure (which may be referred to herein as a first measurement pressure value) and the measured second pressure (which may be referred to herein as a second measurement pressure value) may be transmitted to the controller 360.

The controller 360 may obtain a first estimated force from the first and second measurement pressure values. For example, in the controller 360, a first acting force exerted on the pressuring member 343 may be obtained by multiplying a first and the first measurement pressure value. In the controller 360, a second acting force exerted on the pressuring member 343 may be obtained by multiplying a second area and the second measurement pressure value. Directions of the first and second acting forces may be opposite to each other. In the controller 360, a first estimated force may be calculated using the following equation 1.

F₁₁=(P₁₁×A₁)−(P₂₁×A₂)+W Equation 1
(F₁₁: first estimated force, P₁₁: first measurement pressure value, P₂₁: second measurement pressure value, A₁: first area, A₂: second area, and W: weight value)

The correction method may include obtaining a first real force, which is a real force of the pressuring member 343 in the first state (in S15). When the pressuring member 343 is in the first state, all forces acting on the pressuring member 343 may be in an equilibrium state. As an example, the total resultant force acting on the pressuring member 343 may be zero. Thus, when the pressuring member 343 is in the stationary state, the first real force may be zero.

The correction method may include obtaining a first error, which is a difference between the first real force and the first estimated force (in S20). For example, in the controller 360, the first error may be determined as the difference between the first real force and the first estimated force. The first error may be determined by subtracting the first estimated force from the first real force.

The correction method may include correcting the first estimated force using the first error (in S25). For example, in the controller 360, the first error may be added to the first estimated force to correct the first estimated force.

The correction method may include obtaining a second estimated force, which is an estimated force of the pressuring member in a second state (in S30). The obtaining of the second estimated force may include measuring a third pressure of the first space S1 and a fourth pressure of the second space S2, in the second state. As an example, in the second state, the first pressure sensor 3451 may measure the third pressure of the first space S1, and the second pressure sensor 3452 may measure the fourth pressure of the second space S2. The measured third pressure (which may be referred to herein as a third measurement pressure value) and the measured fourth pressure (which may be referred to herein as a fourth measurement pressure value) may be transmitted to the controller 360. In the second state, the pressure supply unit 350 may be prohibited from providing the pressure to the first space S1.

In the controller 360, the second estimated force may be determined in the same manner as that for the first estimated force. For example, a third acting force exerted on the pressuring member 343 may be determined by multiplying the first area and the third measurement pressure value, and a fourth acting force exerted on the pressuring member 343 may be determined by multiplying the second area and the fourth measurement pressure value. In the controller 360, the second estimated force may be calculated using the following equation 2.

F₂₁=(P₁₂×A₁)−(P₂₂×A₂)+W Equation 2
(F₂₁: second estimated force, P₁₂: third measurement pressure value, P₂₂: fourth measurement pressure value, A₁: first area, A₂: second area, W: weight value)

As an example, the second estimated force may be determined by adding the third acting force to a weight value of the pressuring member 343 and then subtracting a value of the fourth acting force from the resultant value.

The correction method may include obtaining a second real force, which is a real force of the pressuring member 343 in the second state (in S35). Here, a value (which may be referred to herein as a first input pressure value) of pressure, which is provided to the first space S1 from the pressure supply unit 350 may be zero. The controller 360 may obtain a value of pressure (which may be referred to herein as a second input pressure value) that is provided to the second space S2 from the pressure supply unit 350 in the second state. In the controller 360, a fifth force may be determined by multiplying the input pressure value and the second area. In the controller 360, a weight value of the pressuring member 343 and the fifth force may be used to determine the second real force. As an example, in the controller 360, the second real force may be calculated using the following equation 3.

F₂₂=(P₁₃×A₁)−(P₂₃×A₂)+W=W−(P₂₃×A₂) Equation 3
(F₂₂: second real force, P₁₃: first input pressure value, P₂₃: second input pressure value, A₁: first area, A₂: second area, W: weight value)

In an exemplary embodiment of the present inventive concept, the second real force F₂₂ may be determined by subtracting the fifth force (i.e., P₂₃×A₂) from the weight value (W) of the pressuring member 343. The second input pressure value may correspond to a value of the pressure generated by the pressure supply unit 350.

The correction method may include obtaining a second error, which is a difference between the second estimated force and the second real force (in S40). For example, in the controller 360, the second error may be determined as the difference between the second real force and the second estimated force. The second error may be determined by subtracting the second estimated force from the second real force.

The correction method may include correcting the second estimated force (in S45). Referring to FIG. 9, the controller 360 may determine whether the first error corresponds to the second error (in S46). In an exemplary embodiment of the present inventive concept, when the first error is equal to the second error, it may be said that the first and second errors correspond to each other. In an exemplary embodiment of the present inventive concept, when a difference between the first and second errors is within a predetermined tolerance range, it may be said that the first and second errors correspond to each other.

When the first error corresponds to the second error, the controller 360 may correct the second estimated force using the first error or second error (in S47). For example, when the first error corresponds to the second error, the controller 360 may determine that a difference between the estimated force and the real force is unchanged. In this case, the controller 360 may correct the second estimated force by adding the first or second error to the second estimated force.

When the second error does not correspond to the first error, the controller 360 may obtain a value of error slope, using the first and second estimated forces and the first and second errors (in S48). For example, when the first and second errors do not correspond to each other, the controller 360 may determine that a difference between the estimated force and the real force is changed. In this case, the controller 360 may determine a first numerical value, which is determined by subtracting the first error from the second error, and a second numerical value, which is determined by subtracting the first estimated force from the second estimated force. In the controller 360, the first and second numerical values may be used to obtain the value of error slope. For example, in the controller 360, the value of error slope may be calculated using the following equation 4.

eₐ=(e₂−e₁)/(F₂₁−F₁₁) Equation 4
(eₐ: value of error slope, e₁: first error, e₂: second error, F₁₁: first estimated force, F₂₁: second estimated force)

In an exemplary embodiment of the present inventive concept, the value of error slope eₐ may be given by the first numerical value (i.e., e₂−e₁) by the second numerical value (i.e., F₂₁−F₁₁).

The controller 360 may correct the second estimated force using the value of error slope (in S49). For example, in the controller 360, the second estimated force may be corrected using the following equation 5.

F₂₃=(1+eₐ)×F₂₁ Equation 5
(eₐ: value of error slope, F₂₁: second estimated force, F₂₃: corrected magnitude of second estimated force)

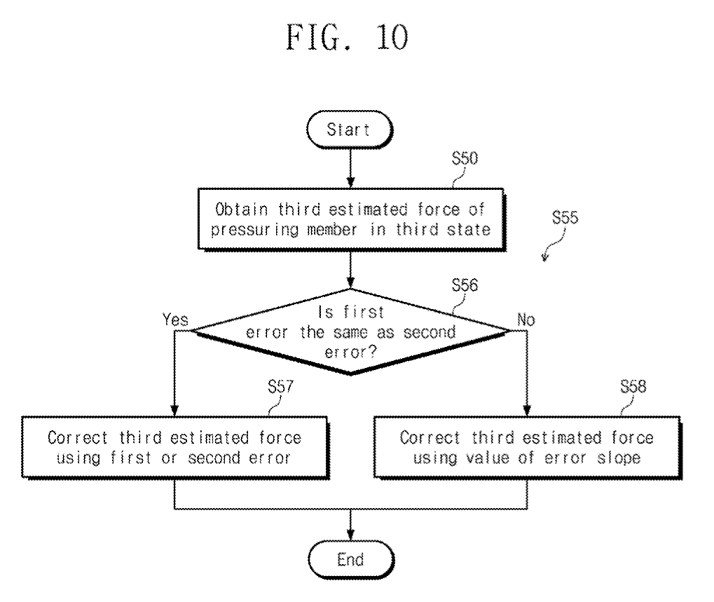

FIG. 10 is a flow chart illustrating a step of correcting a third estimated force using the first and second errors of FIG. 8.

Referring to FIGS. 4 and 10, a method of correcting an estimated force of a bonding apparatus may include obtaining a third estimated force, which is an estimated force of the pressuring member in a third state (in S50). The obtaining of the third estimated force may include measuring a fifth pressure of the first space S1 and a sixth pressure of the second space S2 in the third state, which is different from the first and second states. For example, in the third state, the first pressure sensor 3451 may measure the fifth pressure of the first space S1, and the second pressure sensor 3425 may measure the sixth pressure of the second space 82. The measured fifth pressure (which may be referred to herein as a fifth measurement pressure value) and the measured sixth pressure (which may be referred to herein as a sixth measurement pressure value) may be transmitted to the controller 360.

In the controller 360, a third estimated force may be obtained from the fifth and sixth measurement pressure values by the same method as that for the first estimated force. For example, a fifth acting force exerted on the pressuring member 343 may be determined by multiplying the first area and the fifth measurement pressure value, and a sixth acting force exerted on the pressuring member 343 may be determined by multiplying the second area and the sixth measurement pressure value. The third estimated force may be determined by adding the fifth acting force to the weight value of the pressuring member 343 and then subtracting a value of the sixth acting force from the resultant value.

The correction method may include correcting the third estimated force (in 555). For example, the controller 360 may determine whether a first error corresponds to a second error (in S56). When the first error corresponds to the second error, the controller 360 may correct the third estimated force using the first error or second error (in S57). For example, in the controller 360, the first or second error may be added to the third estimated force to correct the third estimated force.

When the second error does not correspond to the first error, the controller 360 may correct the third estimated force using the value of error slope (in S58). For example, in the controller 360, the third estimated force may be corrected using the following equation 6.

F₃₃=(1+eₐ)×F₃₁ Equation 6
(eₐ: value of error slope, F₃₁: third estimated force, F₃₃: corrected magnitude of third estimated force)

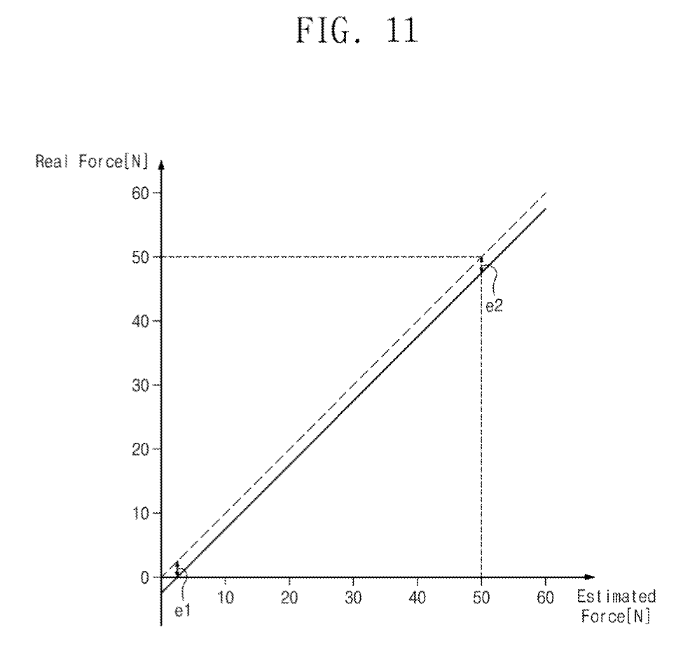

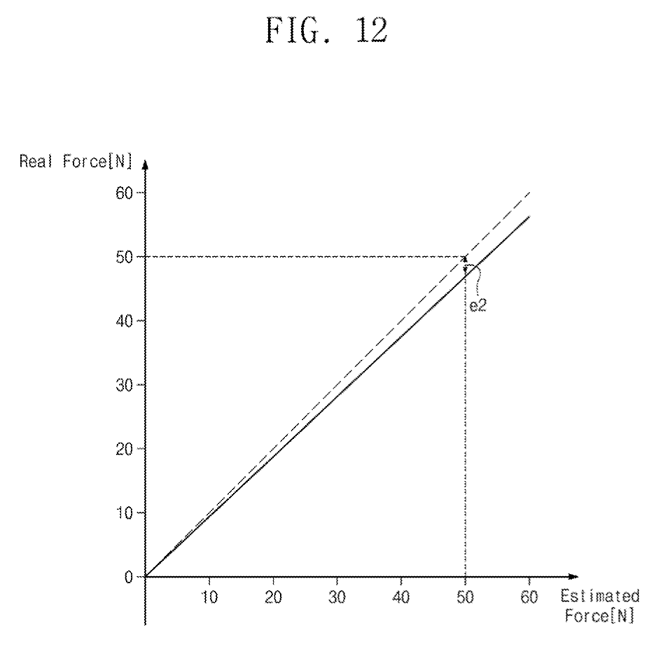

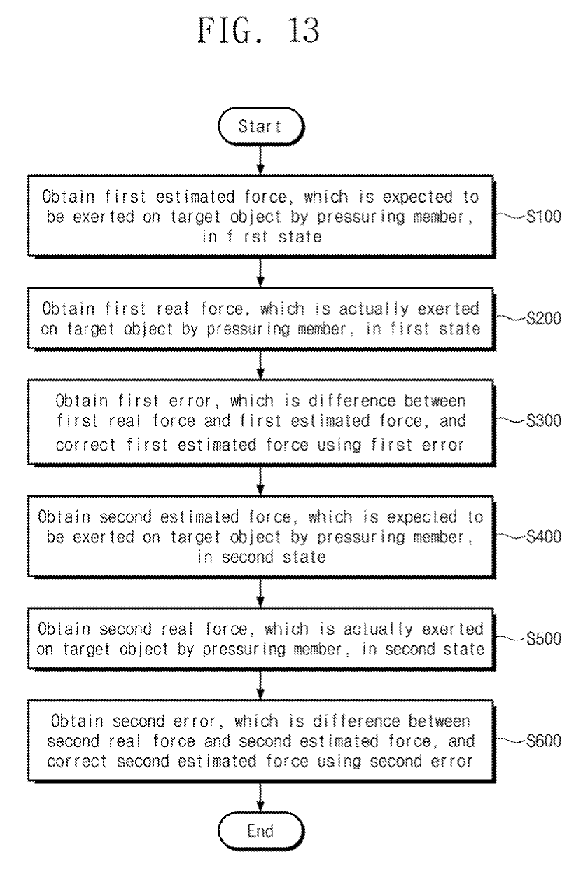

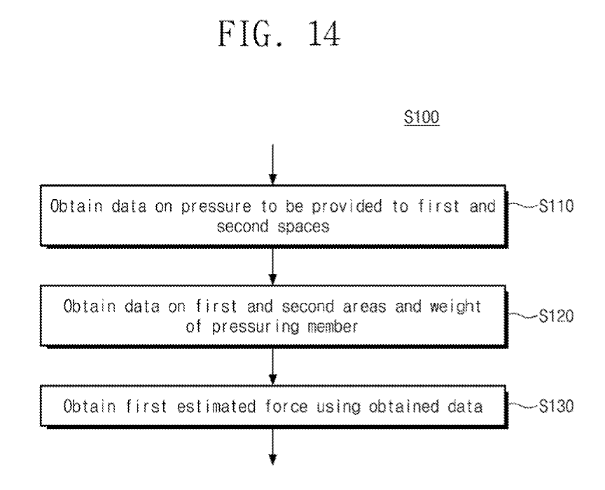

FIG. 11 is a diagram showing the estimated force and the real force, when the first and second errors of FIG. 8 correspond to each other. FIG. 12 is a diagram showing the estimated force and the real force, when the first and second errors of FIG. 8 do not correspond to each other. Referring to FIGS. 12 and 13, solid lines represent the real forces, and the dotted lines represent the estimated forces.

Referring to FIGS. 5 and 8 to 11, when the pressuring member 343 is at rest within the chamber 341 or in the first or stationary state, the controller 360 may obtain the first estimated force of about 2[N] and the first real force of 0[N]. The first error (e1) may be about −2[N].

When the pressure supply unit 350 is prevented from providing pressure to the first space S1 or is in the second state, the controller 360 may obtain the second estimated force of about 50[N] and the second real force of about 48[N]. Thus, the second error (e2) may be about −2[N], and the first and second errors may correspond to each other. In this case, the controller 360 may correct the estimated force by adding the first or second error to the estimated force.

Referring to FIGS. 5, 8, 9, 10, and 12, when the pressuring member 343 is at rest within the chamber 341 or in the first state, the controller 360 may obtain the first estimated force of 0[N] and the first real force of 0[N]. The first error may be zero (see, e.g., a first error e1 is not illustrated in FIG. 12).

When the pressure supply unit 350 is prevented from providing pressure to the first space S1 or is in the second state, the controller 360 may obtain the second estimated force of about 50[N] and the second real force of about 45[N]. Thus, the second error (e2) may be about −5[N], and the first error does not correspond to the second error in this example.

The controller 360 may obtain a value of error slope, using the first and second errors and the first and second estimated forces. In an exemplary embodiment of the present inventive concept, the value of error slope may be about 0.1. Thus, the controller 360 may correct the estimated force in the manner of multiplying the value of error slope and the estimated force and adding the value to the estimated force. As an example, a corrected magnitude of the estimated force may correspond to that of the real force.

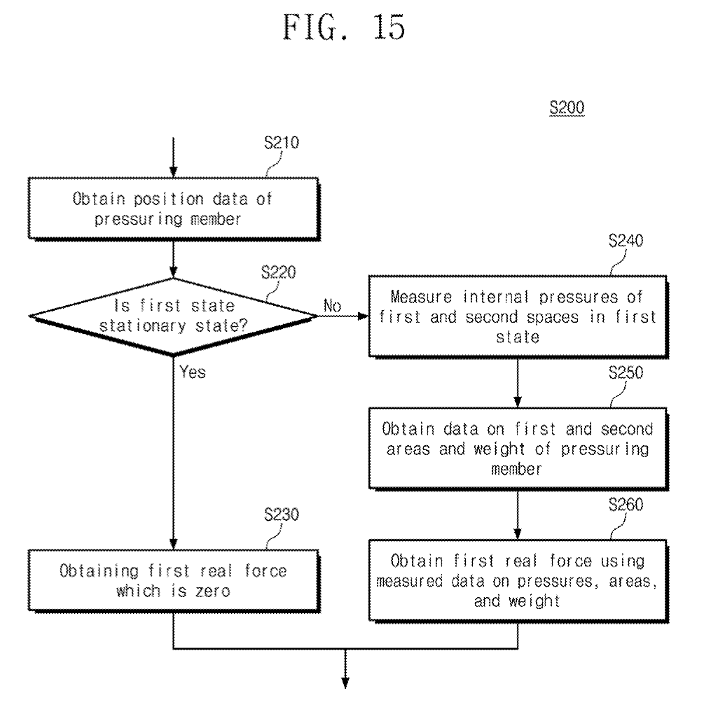

FIG. 13 is a flow chart illustrating another example of a method of correcting an estimated force of the bonding apparatus of FIG. 1. FIG. 14 is a flow chart illustrating a step of obtaining a first estimated force, shown in FIG. 13. FIG. 15 is a flow chart illustrating a step of obtaining a first real force, shown in FIG. 13.

Referring to FIGS. 4, 13, 14, and 15, a method of correcting an estimated force of the bonding apparatus 30 may include obtaining a first estimated force, which is expected to be exerted on a target object by a pressuring member, in a first state (in S100). The method may include obtaining a first real force, which is actually exerted on the target object by the pressuring member, in the first state (in S200). The method may include obtaining a first error, which is a difference between the first real force and a first estimated force, and correcting the first estimated force (in S300). The method includes obtaining a second estimated force, which is expected to be exerted on a target object by the pressuring member in a second state (in S400). The method includes obtaining a second real force, which is actually exerted on the target object by the pressuring member in the second state (in S500). The method includes obtaining a second error, which is a difference between the second real force and the second estimated force, and correcting the second estimated force using the second error (in S600). A corrected magnitude of an estimated force may correspond to that of a real force.

Referring to FIGS. 13 and 14, during the obtaining of the first estimated force (S100), the controller 360 may obtain data (e.g., first pressure data in the first state) on a pressure to be provided to the first and second spaces (in S110). The first pressure data may be included in the input signal I2. The first pressure data may be data on pressure, which is provided to the first and second spaces S1 and S2 from the pressure supply unit 350 in the first state. The first pressure data may include a value of a first pressure, which is provided to the first space S1 from the pressure supply unit 350 in the first state. For example, the value of the first pressure may be a target value of a pressure to be controlled by the pressure control part 353 in the first state. The first pressure data may include a value of a second pressure, which is provided to the second space S2 from the pressure supply unit 350 in the first state. The value of the second pressure may be a target value of a pressure to be generated by the pressure generating part 351 in the first state.

The controller 360 may receive data on an area of the first surface 3431a (hereinafter, a first area), an area of the second surface 3431b (hereinafter, a second area), and a weight value of the pressuring member 343. Thus, the controller 360 may obtain data on the first area, the second area, and the weight value of the pressuring member (in S120). The areas of the first and second surfaces and the weight value of the pressuring member 343 may be predetermined. Here, the first area may be an area of the pressuring member positioned in the first space. The second area may be an area of the pressuring member positioned in the second space.

The controller 360 may obtain the first estimated force using the first pressure value, the second pressure value, the first area, the second area, and the weight value. The controller 360 may obtain the first estimated force using the obtained data (e.g., the data described above) (in S130). For example, in the controller 360, the first estimated force may be calculated using the following equation 11.

F₁₁=(P₁₁×A₁)−(P₂₁×A₂)+W Equation 11
(F₁₁: first estimated force, P₁₁: first pressure value, P₂₁: second pressure value, A₁: first area, A₂: second area, W: weight value)

Referring to FIGS. 13 and 15, during the obtaining of the first real force in the first state (in S200), the position sensor 3453 in the first state may measure a position of the pressuring member 343 in the chamber 341. Thus the position sensor 3453 may obtain position data of the pressuring member (in S210). The controller 360 may receive position data on the pressuring member 343 from the position sensor 3453. Here, the first real force may be a force that is actually exerted on the target object P by the pressuring member 343 in the first state.

In the controller 360, the position data and a predetermined time data may be used to determine whether the first state is a stationary state (in S220). For example, if the pressuring member 343 is positioned at the same position during a predetermined time interval, the controller 360 may determine that the first state is the stationary state. The first state may be a state, in which the pressuring member 343 is at rest at a predetermined position within the chamber 341. In an exemplary embodiment of the present inventive concept, the first state may be a state, in which the pressuring member 343 is at rest at an arbitrary position within the chamber 341.

When the pressuring member 343 is in the stationary state, net force acting on the pressuring member 343 may be zero. As an example, a real force exerted on the target object P by the pressuring member 343 may be 0[N]. Thus, when the controller 360 determines that the first state is the stationary state, the controller 360 may obtain the first real force which is zero (in S230).

When the pressuring member 343 is not in the stationary state, the sensor members 360 may measure internal pressures of the first and second spaces (e.g., S1 and S2) in the first state (in S240). For example, the first pressure sensor 3451 may measure the internal pressure of the first space S1, in the first state. The second pressure sensor 3452 may measure the internal pressure of the second space S2 in the first state. The first and second measurement pressure values measured in the first state may be transmitted to the controller 360.

When the pressuring member 343 is not in the stationary state, the controller 360 may obtain data on the first area, the second area, and the weight value of the pressuring member (in S250). When the pressuring member 343 is not in the stationary state, the controller 360 may determine the first real force using the first measurement pressure value, the second measurement pressure value, the first area, the second area, and the weight value. For example, in the controller 360, the first real force may be calculated using the following equation 12. Thus, the first real force may be obtained using measured data on pressures, areas and weight (in S260).

F₁₃=(P₁₃×A₁)−(P₂₃×A₂)+W Equation 12
(F₁₃: first real force, P₁₃: first measurement pressure value, P₂₃: second measurement pressure value, A₁: first area, A₂: second area, W: weight value)

During the correcting of the first estimated force (in S300), the controller 360 may determine a first error, which is a difference between the first estimated force and the first real force. For example, the first error may be determined by subtracting the first estimated force from the first real force. The controller 360 may correct the first estimated force using the first error. For example, in the controller 360, the first error may be added to the first estimated force to correct the first estimated force.

During the obtaining of the second estimated force in the second state (in S400), the controller 360 may obtain a second pressure data in the second state, which is different from the first state. The second pressure data may be included in the input signal I2, which is input in the second state. The second pressure data may be data on pressure, which is provided to the first and second spaces S1 and S2 from the pressure supply unit 350 in the second state. The second pressure data may include a value of a third pressure, which is provided to the first space S1 from the pressure supply unit 350 in the second state. The second pressure data may include a value of a fourth pressure, which is provided to the second space S2 from the pressure supply unit 350 in the second state. In the second state, the pressure supply unit 350 may be prohibited from providing the pressure to the first space S1. Thus, the third pressure value may be zero.

The controller 360 may obtain the second estimated force using the same method as that for the first estimated force. For example, in the controller 360, the second estimated force may be calculated using the following equation 13.

F₂₁=(P₁₂×A₁)−(P₂₂×A₂)+W Equation 13
(F₂₁: second estimated force, P₁₂: third pressure value, P₂₂: fourth pressure value, A₁: first area, A₂: second area, W: weight value)

During the obtaining of the second real force in the second state (in S500), the controller 360 may obtain the second real force using the same method as that for the first real force. For example, in the controller 360, the second real force may be calculated using the following equation 14.

F₂₄=(P₁₄×A₁)−(P₂₄×A₂)+W Equation 14
(F₂₄: second real force, P₁₄: third measurement pressure value, P₂₄: fourth measurement pressure value, A₁: first area, A₂: second area, W: weight value)

The second real force may be a force that is actually exerted on the target object P by the pressuring member 343 in the second state. The third measurement pressure value may be a value of an internal pressure of the first space S1 measured in the second state. The fourth measurement pressure value may be a value of an internal pressure of the second space S2 measured in the second state.

During the correcting of the second estimated force (in S600), the controller 360 may obtain a second error, which is a difference between the second estimated force and the second real force. The controller 360 may determine whether the first and second errors correspond to each other. When the second error corresponds to the first error, the controller 360 may correct the second estimated force using the first or second error (in S630). For example, the controller 360 may correct the second estimated force in the manner of adding the first error to the second estimated force.

When the second error does not correspond to the first error, the controller 360 may obtain a value of error slope using the first and second estimated forces and the first and second errors (in S640). For example, in the controller 360, the value of error slope may be calculated using the following equation 15.

eₐ=(e₂−e₁)/(F₂₁−F₁₁) Equation 15
(eₐ: value of error slope, e₁: first error, e₂: second error, F₁₁: first estimated force, F₂₁: second estimated force)

The controller 360 may correct the second estimated force using the value of error slope (in S650). For example, in the controller 360, the second estimated force may be corrected using the following equation 16.

F₂₂=(1+eₐ)×F₂₁ Equation 16
(eₐ: value of error slope, F₂₁: second estimated force, F₂₂: corrected magnitude of second estimated force)

Referring to FIG. 10, the method of correcting estimated force of the bonding apparatus 30 may further include obtaining a third estimated force in a third state and correcting the third estimated force. The third state may be any state that is different from the first and second states.

During the obtaining of the third estimated force, the controller 360 may obtain a third pressure data in the third state. The third pressure data may correspond to an input signal, which is input in the third state. The third pressure data may be data on pressures, which are provided to the first and second spaces S1 and S2 from the pressure supply unit 350 in the third state. The third pressure data may include a value of a fifth pressure, which is provided to the first space S1 from the pressure supply unit 350 in the third state. The third pressure data may include a value of a sixth pressure, which is provided to the second space S2 from the pressure supply unit 350 in the third state. The controller 360 may obtain the third estimated force using the same method as that for the first estimated force.

During the correcting of the third estimated force, the controller 360 may determine whether the first and second errors correspond to each other. When the second error corresponds to the first error, the controller 360 may correct the third estimated force using the first or second error. When the second error does not correspond to the first error, the controller 360 may correct the third estimated force using the value of error slope. Thus, the controller 360 may correct the third estimated force using the obtained data relatively quickly.

According to some exemplary embodiments of the present inventive concept, by removing a difference between the estimated force and the real force, it may be possible to increase bonding efficiency of a bonding apparatus and to reduce or prevent an occurrence of a target object being broken in a bonding process. In addition, it may be possible to reduce a process time required to obtain a real force of a bonding apparatus. This may make it possible to relatively quickly correct an estimated force and to increase process efficiency in a bonding process.

While the inventive concept has been particularly shown and described with reference to exemplary embodiments thereof, it will be understood by those of ordinary skill in the art that various changes in form and detail may be made therein without departing from the spirit and scope of the inventive concept.

What is claimed is:

1. A method of correcting an estimated application of a force, comprising:
measuring a first pressure of a first space in a chamber of a bonding apparatus and a second pressure of a second space in the chamber in a first state, wherein a pressuring member positioned in the chamber separates the first space from the second space, wherein in the first state a pressuring member is at rest within the chamber, and wherein the pressuring member is moveable within the chamber;
obtaining a first estimated force, wherein the first estimated force is an estimated force of the pressuring member in the first state, using the measured first and second pressures;
obtaining a first error, wherein the first error is a difference between a first real force and the first estimated force, and wherein the first real force is a real force of the pressuring member in the first state; and
correcting the first estimated force using the first error.

2. The method of claim 1, wherein the obtaining of the first estimated force comprises:
obtaining a first acting force by multiplying the first pressure and an area of a first surface of the pressuring member, wherein the first surface is positioned in the first space; and
obtaining a second acting force by multiplying the second pressure and an area of a second surface of the pressuring member, wherein the second surface is positioned in the second space and faces the first surface, and
wherein the first estimated force is determined by adding a value obtained by subtracting the second acting force from the first acting force, and a predetermined weight value of the pressuring member.

3. The method of claim 1, wherein the first real force is zero.

4. The method of claim 1, further comprising:
measuring a third pressure of the first space and a fourth pressure of the second space in a second state, in which a pressure supply unit is prohibited from providing a pressure to the first space;
obtaining a second estimated force, wherein the second estimated force is an estimated force of the pressuring member in the second state, using the measured third and fourth pressures;
obtaining a second real force, wherein the second real force is actually exerted on the pressuring member in the second state, using a value of a pressure provided to the second space from a pressure supply unit in the second state; and
obtaining a second error, wherein the second error is a difference between the second estimated force and the second real force.

5. The method of claim 4, further comprising correcting the second estimated force using the first or second error, when the second error is substantially the same as the first error.

6. The method of claim 5, further comprising:
measuring a fifth pressure of the first space and a sixth pressure of the second space, in a third state different from the first and second states;
obtaining a third estimated force, wherein the third estimated force is an estimated force of the pressuring member in the third state, using the measured fifth and sixth pressures; and
correcting the third estimated force using the first or second error.

7. The method of claim 4, wherein, when the second error is not substantially the same as the first error, the method further comprises:
obtaining a value of error slope using the first and second estimated forces and the first and second errors; and
correcting the second estimated force using the value of error slope.

8. The method of claim 7, further comprising:
measuring a fifth pressure of the first space and a sixth pressure of the second space in a third state different from the first and second states;
obtaining a third estimated force, wherein the third estimated force is a force expected to be exerted on the pressuring member, using the measured fifth and sixth pressures; and
correcting the third estimated force using the value of error slope.

9. The method of claim 7, wherein the obtaining of the value of error slope comprises:
obtaining a first numerical value by subtracting the first error from the second error; and
obtaining a second numerical value by subtracting the first estimated force from the second estimated force,
wherein the value of error slope is determined by dividing the first numerical value by the second numerical value.

10. The method of claim 4, wherein the obtaining of the second estimated force comprises:
obtaining a third acting force by multiplying the third pressure and an area of a first surface of the pressuring member, wherein the first surface is positioned in the first space; and
obtaining a fourth acting force by multiplying the fourth pressure and an area of a second surface of the pressuring member, wherein the second surface is positioned in the second space and faces the first surface, and
wherein the second estimated force is determined by adding a value obtained by subtracting the fourth acting force from the third acting force, and a weight value of the pressuring member.

11. The method of claim 4, wherein, in the second state, a value of a pressure provided to the first space from the pressure supply unit is zero.

12. The method of claim 1, further comprising:
measuring a position of the pressuring member in the chamber to obtain position data; and
determining whether the pressuring member is in the first state using the position data.

13. A method of correcting an estimated application of a force, comprising:
measuring a first pressure of a first space in a chamber and a second pressure of a second space in the chamber, wherein a pressuring member positioned in the chamber is moveable, wherein the pressuring member separates the first space from the second space, and wherein a first real force exerted on the pressuring member is zero;
obtaining a first estimated force, wherein the first estimated force is a force expected to be exerted on the pressuring member in a first state, using the measured first and second pressures;
obtaining a first error, wherein the first error is a difference between the first real force and the first estimated force; and
correcting the first estimated force using the first error.

14. The method of claim 13, further comprising:
measuring a position of the pressuring member in the chamber to obtain position data; and
determining whether the pressuring member is in a stationary state within the chamber using the position data.

15. The method of claim 13, wherein the obtaining of the first estimated force comprises:
obtaining a first acting force by multiplying the first pressure and an area of a first surface of the pressuring member, wherein the first surface is positioned in the first space; and
obtaining a second acting force by multiplying the second pressure and an area of a second surface of the pressuring member, wherein the second surface is positioned in the second space and faces the first surface, and
wherein the first estimated force is determined by adding a value, which is obtained by subtracting the second acting force from the first acting force, and a predetermined weight value of the pressuring member.

16. A method of correcting application of a force, comprising:
measuring a first pressure of a first space in a chamber and a second pressure of a second space in the chamber, wherein a pressuring member positioned in the chamber is moveable, wherein the pressuring member separates the first space from the second space, and wherein a first real force exerted on the pressuring member is zero;
obtaining a first estimated force, wherein the first estimated force is a force expected to be exerted on the pressuring member in a first state, wherein the first estimated force is calculated by using the equation F₁₁=(P₁₁×A₁)−(P₂₁×A₂)+W,
wherein F₁₁ is the first estimated force, P₁₁ is the first pressure of the first space, P₂₁ is the second pressure of the second space, A₁ is an area of the pressuring member positioned in the first space, A₂ is an area of the pressuring member positioned in the second space and W is a weight of the pressuring member;
obtaining a first error, wherein the first error is a difference between the first real force and the first estimated force; and
correcting the first estimated force using the first error.

17. The method of claim 16, further comprising:
measuring a position of the pressuring member in the chamber to obtain position data; and
determining whether the pressuring member is in a stationary state within the chamber using the position data.

18. The method of claim 16, wherein the first real force is zero.

19. The method of claim 16, further comprising:
measuring a third pressure of the first space and a fourth pressure of the second space in a second state, in which a pressure supply unit is prohibited from providing a pressure to the first space;
obtaining a second estimated force, wherein the second estimated force is an estimated force of the pressuring member in the second state, using the measured third and fourth pressures;
obtaining a second real force, wherein the second real force is actually exerted on the pressuring member in the second state, using a value of a pressure provided to the second space from a pressure supply unit in the second state; and
obtaining a second error, wherein the second error is a difference between the second estimated force and the second real force.

20. The method of claim 19, wherein the second estimated force is calculated using the equation F₂₁=(P₁₂×A₁)−(P₂₂×A₂)+W,
wherein F₂₁ is the second estimated force, P₁₂ is the third pressure of the first space, P₂₂ is the fourth pressure of the second space, A₁ is the area of the pressuring member positioned in the first space, A₂ is the area of the pressuring member positioned in the second space and W is the weight of the pressuring member.
